(19) United States
(12) Patent Application Publication
(10) Pub. No.: US 2022/0299380 A1
(43) Pub. Date: Sep. 22, 2022

(54) DEVICE FOR PERFORMING AN ELECTRICAL MEASUREMENT ON A MEASURING LAYER

(71) Applicant: Schreiner Group GmbH & Co. KG, Oberschleißheim (DE)

(72) Inventor: Johannes BECKER, Ilmmuenster (DE)

(73) Assignee: Schreiner Group GmbH & Co. KG, Oberschleißheim (DE)

(21) Appl. No.: 17/636,494

(22) PCT Filed: Aug. 4, 2020
(86) PCT No.: PCT/EP2020/071879

§ 371 Date: Feb. 18, 2022

(30) Foreign Application Priority Data
Aug. 20, 2019 (DE) 10 2019 122 364.4

(51) Int. Cl. G01K 13/10; G01K 7/18

(52) U.S. Cl. CPC G01K 13/10; G01K 7/18

(57) ABSTRACT

A device for performing or enabling an electrical measurement on a measurement layer includes: at least one measurement layer having a layer thickness, and electrical connections connected to and/or adjacent to and serving to determine the electrical resistance of the at least one measuring layer. At least some electrical connections are connected to or adjacent to different length portions of the at least one measuring layer, whereby a measurement for determining the electrical resistance of the at least one measuring layer in the direction of its layer thickness is carried out or made possible. At least some of the electrical connections are connected to or adjacent to different, preferably mutually opposite, surfaces of the at least one measuring layer, whereby a measurement for determining the electrical resistance of the at least one measuring layer is carried out or made possible in the direction transverse to its layer thickness.

The application relates to a device that performs an electrical measurement on at least one measurement layer or at least enables such a measurement on a measurement layer.

Sensors or other devices often have a layer or material layer whose ohmic resistance is measured.

Such a layer is hereinafter called a measuring layer, since its electrical resistance—for example, when it is in contact with a surrounding material, medium or volume—is measured or is used for some other measurement. Ultimately, a completely different parameter may also be of interest, but it influences the electrical resistance of the layer and can thus be measured indirectly.

The measuring layer whose resistance, in particular specific resistance, is determined by measurement can in particular be an electrical resistance layer made of a suitable material. From the ohmic resistance, if the layer dimensions are known, the specific resistance can be calculated and from this in turn the parameter (and if necessary also adjustable and controllable); for example the temperature.

Furthermore, a sensor or other device has electrical connections that extend to the measurement layer; in particular, electrical conductor paths. The measuring layer and the electrical connections can be applied by printing or other means; for example, on a printed circuit board.

When dimensioning print-technically or otherwise applied layers, in particular structured layers, the lateral dimensions in directions transverse to the layer thickness can usually be specified very precisely. Control of layer thickness, on the other hand, is much more difficult from a manufacturing standpoint; manufacturing tolerances or other variations in layer thickness, although they may be more critical than lateral contours, are therefore more difficult to avoid and control. In the case of ohmic resistors, for example, conventional attempts are made to reduce variations in actual resistance values from desired ohmic resistance values by connecting several such resistors in parallel, by temperature treatments, or by laser trimming, or by varying the composition of the material to be printed for the resistors themselves.

The difficulty in controlling the thickness of layers to be applied, in particular layers to be printed on, does in principle affect all types of materials, i.e. printed conductor paths as well. However, in the case of structures serving as conductor paths, the conductor path thickness is usually not critical or at least not in a critical region, for example because of the high conductivity or the overall sufficiently large conductor cross-section.

On the other hand, such layers or surface areas of applied materials which do not or not exclusively serve as conductor paths and/or in which the electrical resistance (the ohmic resistance, in particular the specific ohmic resistance) is to be measured and/or adjusted are referred to in this application as measuring layers. In the case of such layers serving measurement purposes, the influence of their layer thickness is often critical, for example in the case of layer thickness variations due to manufacturing tolerances, and has a detrimental effect on the accuracy and reliability of the measurement result.

It is the object of the present application to provide a device with at least one measuring layer, on which electrical measurements are possible and in which measurements the accuracy of these measurements is no longer falsified by the layer thickness of the measuring layer or a fluctuation of this layer thickness. In particular, a device is to be provided on whose measuring layer electrical measurements can be carried out or at least made possible in such a way that a value for the electrical resistance or for a parameter influencing the electrical resistance which is compensated for influences of the layer thickness, i.e. which is independent of the actual layer thickness, can be measured and/or determined.

This object is solved by the device of claims 1, 14 and 18.

According to this application, it is provided that two measurements are made on the measuring layer and are linked to each other, namely a measurement of the electrical resistance (or of a property derived therefrom, usually also electrical) in the direction of the layer thickness itself and a second measurement of the same property but in the direction transverse to the layer thickness, i.e. in the lateral direction.

Conventionally, the measurement is usually made exclusively transverse to the layer thickness, i.e. along the lateral dimensions of the measurement layer, namely in the lateral and horizontal directions, respectively, between the two electrical connections that contact the measurement layer on different surface areas above the printed circuit board. In such a conventional measurement, the target value, average value or estimated value for the layer thickness of the measuring layer aimed at in terms of production technology is indeed specified, once during the producing of the object as a target value for dimensioning the measuring layer and often also additionally as a stored numerical value in the software or hardware of the electronic measuring circuit or the device, in order to be able to calculate the electrical resistance of the layer or the other parameter from this and from the other (measurement) data. Even if the measurement and the subsequent calculation are carried out accurately, measurement errors will occur in case of deviations of the actual layer thickness from the manufacturing specification and/or from the stored numerical value.

The present application avoids such measurement errors and provides that the influence of the layer thickness of the measurement layer on the measurement result is compensated for by performing another, additional measurement in which a current is passed through the measurement layer (or a voltage is applied and/or tapped or measured) in the direction parallel to its layer thickness (i.e., vertically instead of horizontally, for example). The result of this additional measurement is combined with the result of the measurement in the direction transverse to the layer thickness in such a way that such a value can be calculated for the resistivity (or for a parameter to be measured which influences this resistivity) and/or such a calculation formula can be applied which no longer depends on the layer thickness of the measuring layer. As a result, the determined value (for the resistivity or the other parameter) becomes independent of the influence of the layer thickness, i.e. an error-free, more objective value for the resistivity or for the parameter to be measured with the aid of the resistivity (such as temperature) is obtained.

Some exemplary embodiments are described below with reference to the figures. They show:

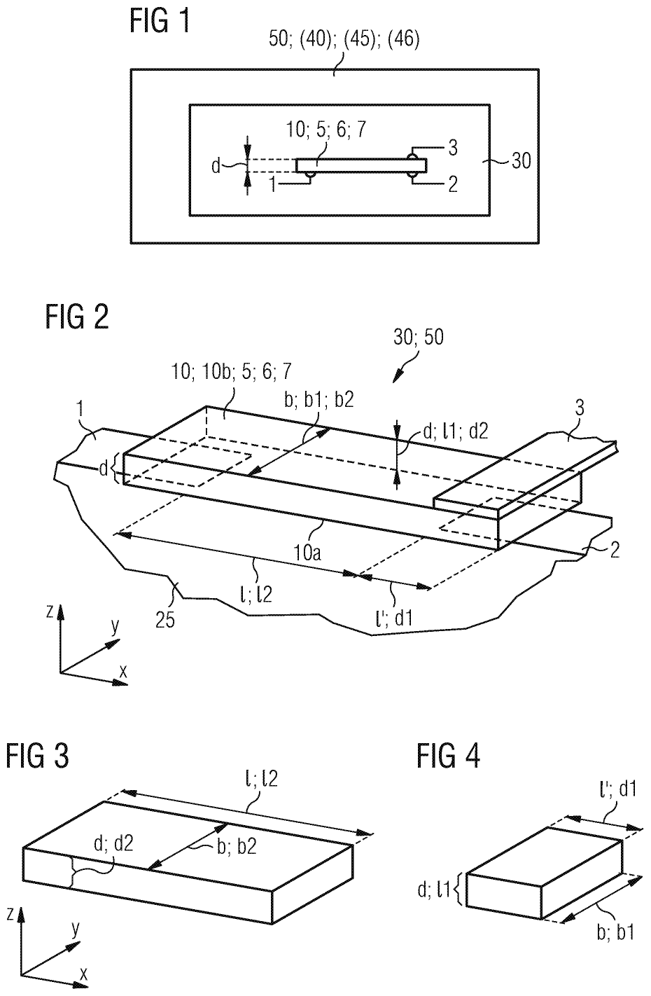

FIG. 1 a schematic illustration of a device with a measuring circuit comprising a measuring strip,

FIG. 2 a perspective view of a first exemplary embodiment with respect to the measurement layer geometry and its contact,

FIGS. 3 and 4 different partial sections of the measuring layer from FIG. 2,

FIG. 5 an equivalent circuit diagram for the measuring circuit of FIGS. 2 to 4,

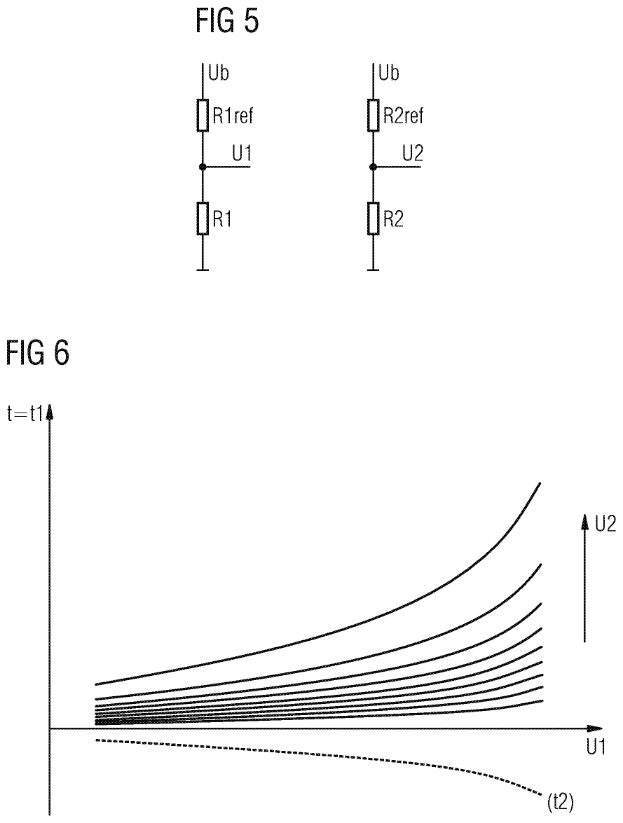

FIG. 6 the dependence of a parameter dependent on the resistivity of the measuring layer on two measuring voltages from FIG. 5,

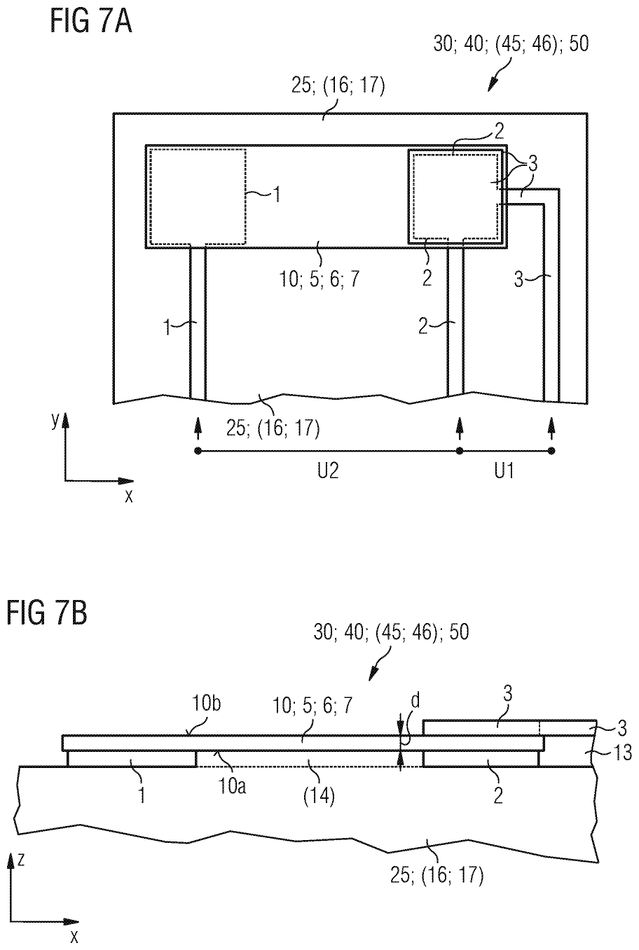

FIGS. 7A and 7B a top view and a cross-sectional view of the measuring circuit of FIGS. 2 to 5,

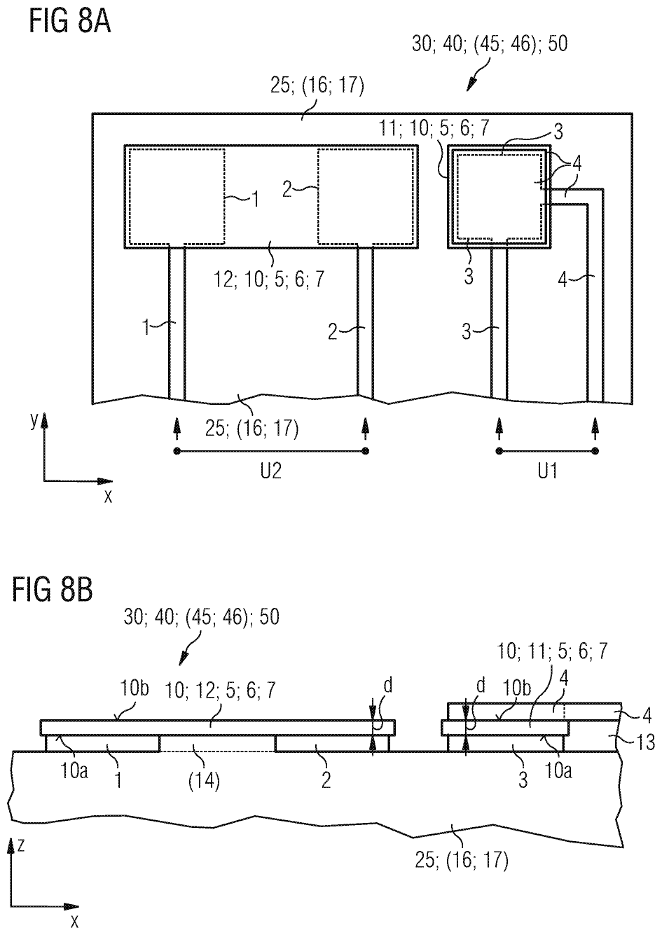

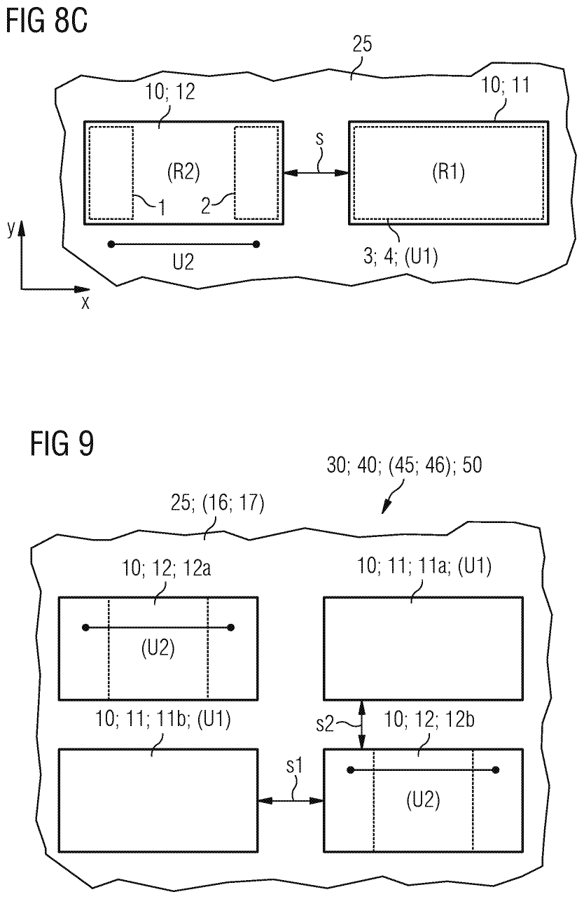

FIGS. 8A and 8B a modified embodiment of the device and its measuring circuit, respectively, with two separate measuring layers of equal thickness,

FIG. 8C a modification compared to FIGS. 8A and 8B with respect to the lateral dimensions of the measuring layers,

FIG. 9 a modification compared to FIG. 8C with a total of four measuring layers,

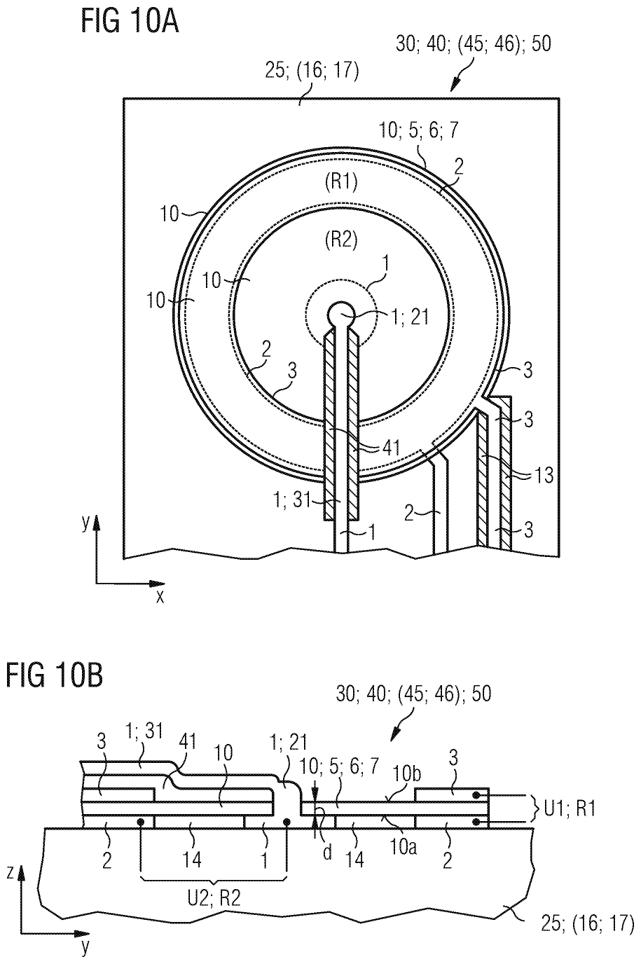

FIGS. 10A and 10B an alternative embodiment with respect to the geometry of the measuring layer and its connections,

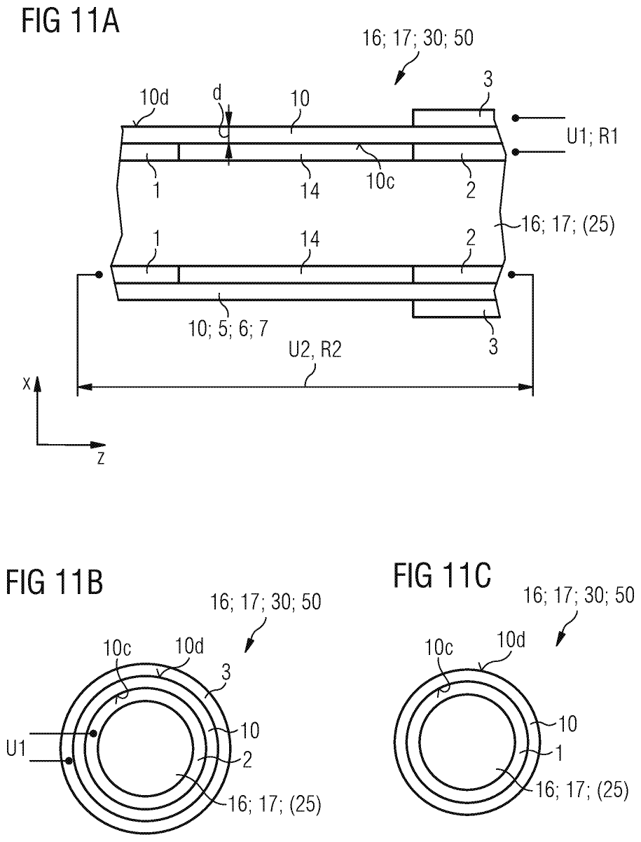

FIGS. 11A to 11C an exemplary embodiment with a non-planar measuring layer,

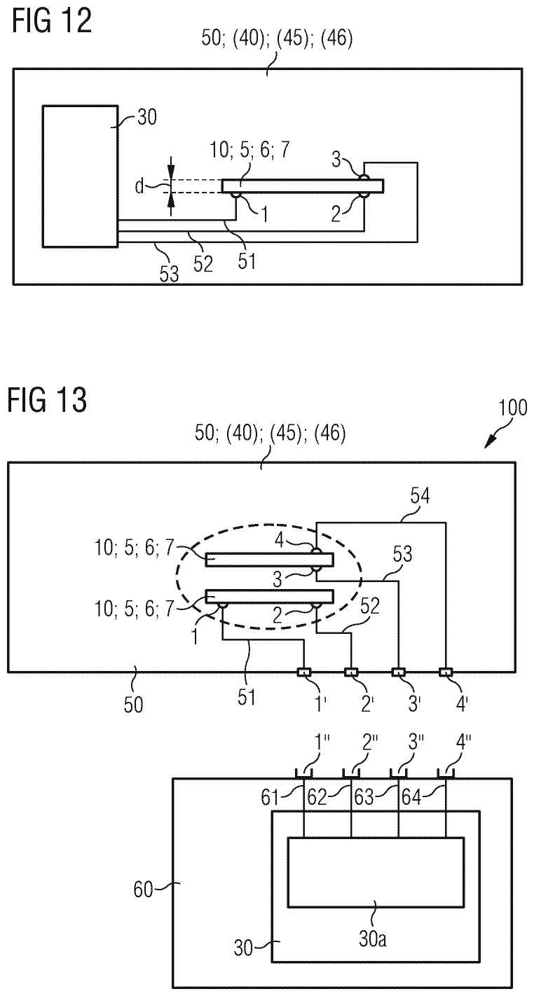

FIG. 12 an alternative embodiment to FIG. 1 of a device with at least one measuring layer, and

FIG. 13 an embodiment alternative to FIGS. 1 and 12, in which an embodiment is provided with at least one measuring layer but without a measuring circuit and further with a measuring device separate or independent from the embodiment, which together form an arrangement for performing electrical measurements on the measuring layer.

FIG. 1 shows a purely schematic illustration of a device 50 with a measuring circuit 30, which comprises a measuring layer 10; preferably a measuring layer 10 deposited on a substrate or other base or carrier. The measuring layer 10 may in particular be a printed layer 5, for example of printing paste 7 or other printable varnish (printing varnish); alternatively also a material layer applied by another application process. In particular, the material of this layer may be a material which, prior to application to the substrate or base or other carrier, is present only in liquid or pasty form, as an emulsion or as a suspension (in particular as a printing ink mass) and is thus initially shapeless, i.e. is present without a solid physical form. Since there is thus no specified contour of this material mass prior to application, the printing process or other application process (including subsequent post-processing, if necessary) is decisive for the shaping of the material layer formed from this mass, which later serves as the measuring layer 10. In particular, the layer thickness d, which is typically much smaller for printed layers than the lateral dimensions parallel to the substrate, is more difficult to control, measure and/or correct in printing and other application processes. In particular, for printed layers intended to be used as an electrical resistor, especially as a resistive resistance element or passive electronic device, it is a disadvantage that printing presses are not as good at maintaining an accurate thickness of the printed layer, nor is it as easy to perform their follow-up inspection with a camera as it is for the lateral length and width dimensions of the produced printed layer on the substrate, carrier or other substrate. Traditionally, a certain tolerance of the layer thickness of measured layers was either accepted or adjusted by time-consuming and labor-intensive post-processing, for example by laser trimming.

In the case of the device illustrated in FIG. 1, the layer thickness d of the printed measuring layer 5 or 10 may therefore be subject to fluctuations, i.e. may vary depending on the specimen of the article. According to the present application, the device 50 or its measuring circuit 30 is designed in such a way that the influence of the actual layer thickness d on the measurement result is taken into account and compensated. For this purpose, it is provided that two measurements are carried out and combined with each other in order to obtain a measured value resulting from both measurements which is independent of the size of the layer thickness d. In order to carry out the two measurements, three electrical connections 1, 2 and 3 are formed on the measuring layer 10 in FIG. 1. The concrete spatial positions of these connections relative to the measuring layer can be seen in the other following figures.

FIG. 1, but also the following figures, are to be understood purely schematically, i.e. without defining any spatial proportions or dimensions; in particular, the measuring layer 10 and/or the plurality of electrical connections 1, 2, 3, 4 may also be arranged (wholly or partially) outside a housing of the device 50 and/or the measuring circuit 30 instead of inside, for example in order to come into contact with an external environment, such as a gas or other medium, pressure, moisture or other interaction (see above) with the measuring layer. For example, the at least one measuring layer and end-side regions of the electrical connections may be arranged in a housing window or on, in, or on a probe, i.e., a measuring probe, or may be arranged in an otherwise exposed region of the device 50 and/or its measuring circuit 30.

The measuring layer is in particular a layer of a material whose ohmic resistance, in particular whose specific (ohmic) resistance Rst is to be measured. For many materials, the exact level of the resistivity depends on a parameter T; usually on the temperature t, but often also on other influencing variables to be measured instead of the temperature, for example on a pressure exerted on the measuring layer 10 due to the atmosphere or another surrounding medium, on the humidity (e.g. relative humidity), brightness or other radiation intensity, a pH value or a concentration of a certain substance, chemical or component of a material, a solution, an emulsion or suspension or a body fluid such as blood (e.g. blood sugar concentration) when the surface of the measuring layer comes into contact with them.

In addition to these explicitly mentioned examples, any other physical quantities or parameters t can be considered which can influence the resistance of a measuring layer but which, when conventional measuring instruments are used, provide erroneous measurement results as a result of insufficient layer thickness control of the measuring layer 10 during producing. With the aid of the measuring circuit described herein, it becomes possible to determine a much more precise and reliable measured value for such parameters t and/or the resistivity of the measuring layer.

As distinct from wires, printed circuit boards, substrates or other physically preformed elements of electronic circuits, “layer” here preferably means a coating, in particular printing, applied by application to a substrate, base or other carrier material, the physical-spatial dimensions of which are produced only by the application or coating process (in particular printing process), if necessary also only by subsequent structuring. For example, the measuring layer is a coating (in particular printing, i.e. printed layer) on a printed circuit board or PCB, a label or on another component of the measuring circuit.

A measuring layer is thus, for example, a coating or printing of a material whose resistivity is either itself of interest or merely serves to measure, set and/or regulate the further parameter t. The resistivity of solids or other material mixtures present as condensed matter (printing paste, printing compound, etc.) depends in particular on temperature; for many materials it increases with increasing temperature. Since, in order to determine the resistivity of, for example, a cuboid volume of printing paste, its spatial dimensions, i.e., inter alia, also the layer thickness, must be taken into account, in the case of temperature measurement with a conventional measuring device 50 which comprises a measuring layer 10, the determined value for the temperature t of the measuring layer 10 will depend on the accuracy with which the intended layer thickness d of the measuring layer 10 was maintained during its producing or application, and, in the case of deviations from the desired value, will lead to measurement errors which no longer occur with the measuring device or other device 50 proposed here.

The resistivity of the measuring layer (in particular the ohmic DC resistance) is usually significantly higher than that of a metallic conductor path, but on the other hand is often lower than that of non-conductors. Preferably, measurement layers with a resistivity between 1 Ohm/sq and 1000 Ohm/sq are considered here. Nevertheless, the term “measuring layer” is not limited exclusively to materials of only medium or low conductivity; for example, depending on the application, metal layers can also be used as measuring layers due to their surface properties, for example as a result of catalytic or other surface reactions, and can be suitably dimensioned if necessary.

FIG. 2 shows a perspective view of a first exemplary embodiment with regard to the geometry of the measuring layer 10 and the arrangement of electrical connections 1, 2 and 3 connected thereto. Already the number of three different electrical connections 1, 2, 3, which are all connected to the same measuring layer 10, differs from conventional measuring instruments, where usually no third connection is provided. The third connection 3 is used to perform an additional measurement of electrical resistance, namely in the direction parallel to the layer thickness d of the measuring layer 10, i.e. in the direction of the surface normal perpendicular to the upper side 10b and underside 10a of the measuring layer 10. Again, the measuring layer 10 is, for example, a printed layer 5, such as a printing paste 7 or other printed ink (printing varnish) or, in any case, another coating 6 formed by an application or deposition process. Thus, at least the lateral dimensions in the xy plane, i.e., at least the length dimension and the width of the measuring layer 10 have been specified by the printing process or the other deposition, if necessary by subsequent structuring. In FIG. 2, the measuring layer therefore has a specific length 1 and width b parallel to the surface of the substrate 25, carrier or other substrate. With regard to the length of the measuring layer 10, its entire length is not referred to in FIG. 2, only a section 1 of its length, which bridges the lateral distance between a first connection 1 and a second connection 2, with 1; for the voltage between the connections 1 and 2, this (partial) length 1 is decisive for the further calculations. These connections 1, 2 are, for example, conductor paths brought to the underside of the measuring layer 10, arranged, for example, between the measuring layer 10 and the substrate 25 (or embedded therein), which each contact a surface area of the measuring layer or its underside; the distance between these surface areas corresponds to the partial length 1 of the measuring layer 10 relevant for the measurement.

A third electrical connection 3 is arranged on the upper side 10b of the measuring layer 10, which overlaps, for example, in the lateral direction with the second connection 2, but is arranged on the opposite side 10b of the measuring layer 10 as the second connection 2. The second and third connections 2, 3 serve to carry out a second measurement, in which the electrical resistance of the measuring layer 10 is also still measured in the direction of the layer thickness d or This second measurement results in a linkage of the layer thickness d and the resistivity (or a parameter influencing it) with another measured value; in addition to the linkage achieved by the first measurement (between the connections 1 and 2). Both linkages are combined to obtain therefrom a value actually independent of the layer thickness d, i.e. compensated for the influence of the layer thickness and/or of variations in the layer thickness d, for the measurement variable actually of interest, namely for the value of the resistivity itself and/or for the value of the parameter t influencing the resistivity of the measurement layer 10. For many solids, resistivity depends on temperature; this is referred to here with t. Nevertheless, in principle any parameter can be considered; the letter tin this application is therefore representative of any influencing variable to be measured, monitored and/or regulated with the aid of the measuring circuit 30 and the measuring layer 10.

FIG. 3 shows the section of the measuring layer 10 corresponding to the partial length 1, which becomes relevant for the first measurement, in which the ohmic resistance of the measuring layer 10 is measured in the region between the first and second connections 1, 2. With the respective electrical connections 1, 2, 3, . . . , conductor paths or, in any case, conductive structures approaching the at least one measuring layer 10 are meant in each case; in particular, the contact regions thereof, which in each case directly contact the at least one measuring layer 10.

The electrical resistance, which is generally a complex quantity, is preferably the ohmic resistance, i.e. the DC resistance of the material of the measuring layer 10. For most applications, it is assumed that the measuring layer is formed from an isotropic material whose resistivity is also isotropic, i.e. independent of direction. The overall electrical resistivity R of the sensing layer additionally also depends on the dimensions of the sensing layer 10.

In principle, the ohmic resistance of a material web such as the measuring layer 10 is the product of the resistivity and the length of the measuring layer (in the measuring direction) divided by the cross-sectional area perpendicular to the measuring direction. The measuring direction is the direction along which the current flows or, in any case, the voltage is applied. In the direction perpendicular to it, the material web or the measurement layer has a certain width and a certain thickness. Dividing the ohmic resistance by this thickness gives the sheet resistance RE, which is specified instead of the ohmic resistance, especially for thin layers of very low thickness.

While conventionally only one measuring voltage is applied along a single direction (the main direction of extension) or dimension of the measuring layer (analogous to FIG. 3), it is proposed here to apply and/or tap an additional voltage in the direction of the layer thickness d of the measuring layer.

FIG. 4 shows a further end section of the measuring layer 10 of length l′ adjoining the length 1 in FIG. 3, which, as can be seen in FIG. 2, is arranged between the lower connection 2 and the upper connection 3. Here, an additional current flow occurs between the connections 2, 3, in the direction z parallel to the layer thickness d of the measuring layer 10. Assuming that both connections 2, 3 cover the entire width b=l1 (in the direction y) and also the entire remaining length l′=d1 (in the direction x) on the upper and underside 10b, 10a of the measuring layer 10 in the length section 1′, the ohmic resistance R1 between the connections 2, 3 results for this measurement (FIGS. 2 and 4) in accordance with

$$R 1 = Rs \cdot \frac{l 1}{b 1 \cdot d 1}$$

with l1=d as the distance through the measuring layer 10 along the direction z, which in this (first) measurement also corresponds to the current direction, and with the dimensions b1=b and d1=1′ of the cross-sectional area perpendicular to the current direction. It is idealized that the resistance of the connections is much smaller than that of the measuring layer (otherwise there would be a transition zone where the connection and the measuring layer are adjacent, in which case a correction term would have to be taken into account for l1, i.e. the distance between the inner edges of the connections). For the measurement (FIGS. 2 and 3) between the connections 1, 2, the ohmic resistance R2 results according to

$$R 2 = Rs \cdot \frac{l 2}{b 2 \cdot d 2}$$

with l2=1 as the path length through the measurement layer 10 along the direction x, which is the current direction of this (second) measurement, and with the dimensions b2=b and d2=d of the cross-sectional area perpendicular to this current direction. Reference signs additionally used in FIGS. 2 to 4 for the geometrical dimensions of the measuring layer 10, whose index numbers 1 and 2 indicate the first (perpendicular) and second (horizontal) measurement, respectively, will be further standardized in the course of the following calculation.

FIG. 5 shows an equivalent circuit diagram for part of the measuring circuit 30. The measuring circuit 30 is used to determine the ohmic resistance of the measuring layer, with the aid of voltage measurements. Alternatively, the resistance could also be determined by means of current measurements; the following mathematical derivation with reference to FIG. 5 refers only to the case of resistance determination by means of voltage measurement.

In the measuring circuit 30 (FIG. 5), the ohmic resistance R1 to be determined in each case in the direction of the layer thickness and that R2 in the direction perpendicular to the layer thickness are each connected in series with a respective reference resistor R1ref or R2ref. In between, a measuring voltage U1 or U2 is tapped in each case, the level of which enables the resistivity and ultimately the parameter influencing it to be determined in the further calculation, as a result of both measurements being carried out and combined in order to take into account the influence of the layer thickness d of the measuring layer 10. For both measurements, a direct current voltage is preferably used in each case. Both measurements can optionally be carried out one after the other or simultaneously; in the case of repeated measurement also alternately one after the other or each simultaneously or continuously or at certain time intervals. Assuming that the operating voltage or other total voltage Ub applied to the two series circuits is specified and is the same for both measurements, the respective partial voltage U1 or U2 results from the relative ratio of the resistance at the current-carrying section of the first measuring layer 10 according to FIG. 3 and or FIG. 4 relative to the total resistance, which additionally contains the respective reference resistance according to FIG. 5. Thus, the Tappable voltages are calculated according to

$$U 1 = Ub \cdot \frac{Rs \cdot \frac{l 1}{b 1 \cdot d 1}}{R 1 ref + Rs \cdot \frac{l 1}{b 1 \cdot d 1}} and$$

$$U 2 = Ub \cdot \frac{Rs \cdot \frac{l 2}{b 2 \cdot d 2}}{R 2 ref + Rs \cdot \frac{l 2}{b 2 \cdot d 2}}$$

with Rs as the resistivity (which is often abbreviated as ρ) of the material of the measurement layer 10.

In the following, it is assumed that it is not the resistivity itself that is of interest, but the magnitude of a parameter that influences and, if necessary, changes the resistivity Rs of the material of the measurement layer 10, at least temporarily, during the measurement. Whatever the exact dependence of the resistivity on this parameter t may be, it is in any case possible to specify approximately a linear relationship (as here overall, or alternatively linearized in sections), approximately of the form

Rs=Rs0+a·t,

wherein t is the parameter, a is a proportionality constant indicating the slope of this straight line, and Rs0 is a specified setpoint, average or estimated value for the resistivity determined, for example, for a particular setpoint of the parameter t. This nominal value is also referred to below as Rs_nom, since it refers to a nominal value of resistivity (given a nominal or estimated value for parameter t) that does not necessarily actually correspond to the exact value when measured.

Although any parameter can be used to change the resistivity, for the sake of simplicity only the temperature t is considered as a representative parameter in the following. This results in the following calculations

$$Rst ( t ) = Rs\_nom + \frac{t}{sf}$$

with the reciprocal of sf as the proportionality constant a (the constant a corresponds to the temperature coefficient, which is often abbreviated as α). The factor sf is specified in the unit ° C./Ωm. If another physical or chemical parameter (instead of temperature) is investigated, the unit of sf is also different.

Rs_nom represents the nominal or estimated value of the resistivity at a specified parameter; in this case, at a specified temperature, such as room temperature. In the further calculation, the lateral dimensions b1, d1, b2 and l2 are now assumed to be known (and constant); furthermore also the total voltage Ub, the resistivity constant Rs_nom and the temperature coefficient 1/sf. On the other hand, the critical layer thickness d of the measurement layer 10, referred to as l1 for the first measurement and b2 for the second measurement, is treated as a variable; likewise the temperature t (more generally: the arbitrary parameter t) and the resistivity Rst(t) influenced by it according to the above formula.

For the stress U1 of the first, “vertical” measurement (i.e. in the direction of the layer thickness d; cf. FIG. 4), the following is obtained

$$U 1 - Ub \cdot \frac{Rst ( t ) \cdot \frac{l 1}{b 1 \cdot d 1}}{R 1 ref + Rst ( t ) \cdot \frac{l 1}{b 1 \cdot d 1}} = 0$$

or resolved to l1

$$l 1 ( t , U 1 ) = - \frac{b 1 \cdot d 1 \cdot R 1 ref \cdot U 1}{R 1 \cdot U 1 - Rst ( t ) \cdot Ub}$$

and for the voltage U2 of the “horizontal” resistance measurement (FIG. 3) one gets

$$U 2 - Ub \cdot \frac{Rst ( t ) \cdot \frac{l 2}{b 2 \cdot d 2}}{R 2 ref + Rst ( t ) \cdot \frac{l 2}{b 2 \cdot d 2}} = 0$$

If one substitutes the above formula for Rst(t) and take into account that l1 and d2 are only other abbreviations for the layer thickness d considered in different ways for both individual measurements and are thus identical, one obtains the following using

$$d 2 ( t , U 1 ) = l 1 ( t , U 1 ) = - \frac{b 1 \cdot d 1 \cdot R 1 ref \cdot U 1}{R 1 \cdot U 1 - Rst ( t ) \cdot Ub}$$

as equation for the horizontally applied voltage U2

$$U 2 - Ub \cdot \frac{\frac{( Rs\_nom + \frac{t}{sf} ) \cdot l 2}{b 2 \cdot \frac{b 1 \cdot d 1 \cdot R 1 ref \cdot U 1}{( Rs\_nom + \frac{t}{sf} ) \cdot ( Ub - U 1 )}}}{R 2 ref + \frac{( Rs\_nom + \frac{t}{sf} ) \cdot l 2}{b 2 \cdot \frac{b 1 \cdot d 1 \cdot R 1 ref \cdot U 1}{( Rs\_nom + \frac{t}{sf} ) \cdot ( Ub - U 1 )}}} = 0$$

If the equation is solved for the sought parameter t as a function of the magnitude of both measuring voltages U1 and U2, the two solutions are obtained

$$t 1 ( U 1 , U 2 ) = \frac{sf \cdot ( \begin{matrix}U 2 \cdot Rs\_nom - Ub \cdot Rs\_nom + \\ \sqrt{\frac{\begin{matrix}b 1 \cdot b 2 \cdot d 1 \cdot R 1 ref \cdot R 2 ref \cdot U 1 \cdot U 2 \cdot \\ ( Ub - U 2 )\end{matrix}}{l 2 \cdot ( Ub - U 1 )}}\end{matrix} )}{Ub - U 2} and$$

$$t 2 ( U 1 , U 2 ) = - \frac{sf \cdot ( \begin{matrix}Ub \cdot Rs\_nom - U 2 \cdot Rs\_nom + \\ \sqrt{\frac{\begin{matrix}b 1 \cdot b 2 \cdot d 1 \cdot R 1 ref \cdot R 2 ref \cdot U 1 \cdot U 2 \cdot \\ ( Ub - U 2 )\end{matrix}}{l 2 \cdot ( Ub - U 1 )}}\end{matrix} )}{Ub - U 2}$$

In view of the equivalent circuit diagram shown in FIG. 5 with the ohmic resistors R1, R2, R1ref, R2ref, an increasing curve is to be expected for the function t(U1,U2), whereas the second solution t2(U1,U2) has a decreasing curve. Therefore, the first formula for t=t1(U1,U2) is the physically correct solution to calculate the temperature t or the other parameter t of interest (in general, of the two mathematical formulas above, the physically meaningful one should be chosen as the solution).

As can be seen from the formula for t1(U1,U2), i.e. t(U1,U2), the solution formula depends only on specified, non-critical influencing variables and the measured partial stresses U1,U2, but no longer on the metrologically critical layer thickness d of the measuring layer 10. Also the synonymous abbreviations l1 or d2 no longer appear. The above formula for t1(U1,U2)=t(U1,U2) and the two measurements of U1 and U2 according to FIGS. 2 to 5 provide as calculation result exactly the correct value for the temperature or the other parameter t, adjusted from influences of the layer thickness d. The value for t obtained according to the above formula for t1(U1,U2)=t(U1,U2) is therefore already corrected for the influence of the layer thickness d, i.e. it is more accurate and reliable than with conventional measurements or measuring instruments.

A qualitative idea of the solution formula for t or t1 is given by FIG. 6, in which parameter curves for the magnitude of the parameter value for t (on the vertical axis) are plotted in arbitrary units as a function of the magnitude of the partial voltage U1 measured in the direction of the layer thickness (in the region from 0.5 to 4.5V), in the form of several curves for different values of U2. The greater the value of the partial voltage of U2 in volts, the higher and steeper the corresponding curve t(U1) plotted in FIG. 6. The dashed curve for negative parameter values corresponds to the unphysical solution t2, which is of no significance. Regarding the magnitude of the electrical parameters involved, a total voltage Ub of 5 V can be applied, for example, and the two reference resistors representing the remaining part of the measurement circuit can be, for example, R1ref=2700Ω and R2ref=27 kΩ. The reference value at a specified magnitude of temperature or other parameter t may be, for example, Rs_nom=0.5 Ωm for the resistivity of the material of the sensing layer, and the characteristic description may be, for example, sf=5/Ωm. With respect to the dimensions of the measurement layer 10, the length to be bridged for the horizontal measurement may be, for example, 1=l2=50 mm, the remaining length between the two connections 2 and 3 may be, for example, l′=d1=5 mm, the width in the y direction may be, for example, b=b1=b2=5 mm, and the layer thickness of the measurement layer 10 in the z direction considered by the compensating measurement circuit may be, for example, d=l1=d2=1 mm.

FIGS. 7A and 7B show the exemplary embodiment explained on the basis of FIGS. 1 to 6 once again in plan view and cross-sectional view with respect to the substrate 25 or other carrier or substrate beneath the layer structure formed by the at least one measuring layer 10 and the electrical connections. FIG. 7A shows a top view of the substrate 25 (or a portion thereof). In this embodiment, as in all other embodiments, the region in which the measuring layer 10 is arranged can be designed, for example, as a probe 16 or measuring probe 17 (not shown in greater detail in the illustration); however, this is optional. The electrical connections 1, 2 and 3 have, in addition to a region in the form of a path designed as a lead, laterally outside the dimensions of the measuring layer 10, furthermore a region overlapping with this measuring layer in a surface region in each case, which could also be referred to as a contact surface or contact surface region; here the respective electrical connection 1, 2, 3 or its respective conductor path makes contact with the measuring layer 10. The voltage which can be tapped between the connections 2, 3 is U1 and that between the connections 1, 2 is U2. A cross-sectional view extending along the main extension direction of the sensing layer 10 is illustrated in FIG. 7B. The connections 1 and 2 are arranged, for example, on the underside 10a of the measurement layer 10 between the latter and the substrate 25. The dashed region remaining between them may, for example, be filled with an electrically insulating filler layer 13; alternatively, the sensing layer 10 may be conformally deposited, whereby it sinks slightly between both connections 1, 2 and directly contacts the substrate 25. Also, in the case of the third connection 3, which is illustrated on the upper side 10b of the measuring layer opposite the second connection 2, the lead region of the conductor path 3 may optionally extend in contact with the substrate surface 25 or an insulating layer 14 thereon. The at least one measuring layer 10 is a layer applied to the substrate 25 or the other substrate and the two connections 1, 2; in particular a printed layer 5 of, for example, printing paste 7 or another printable varnish (printing varnish). The at least one measuring layer 10 is in particular a coating 6 which has only obtained its dimensional stability by depositing or coating and in particular printing the respective substrate. Its layer thickness d, shown in FIG. 7B, is neither estimated nor exactly calculated according to this application; instead, its influence is measured by the additional measurement between the connections 2, 3 with the aid of the tapped measurement voltage U1 and is taken into account mathematically when determining the correct parameter value for t. A region between 0.1 μm and several millimeters, for example between 0.1 μm and 5 mm, is suitable as a typical bandwidth for the selected layer thickness d actually realized. However, the double measurement proposed here is also suitable outside this range; ultimately, only the magnitudes of the voltages and currents specify the required coating thicknesses. Otherwise, the explanations given above for FIG. 1 apply to the materials and other properties of the measuring layer 10. With today's printing and other deposition techniques, it is relatively easy to realize that the respective layer thickness d is constant or nearly constant not only over the lateral dimensions of the required measuring layer 10, but also over much larger surface areas; the above bandwidths are merely intended to specify the value that the respective uniform layer thickness can assume in terms of magnitude. With regard to the manner of representation in FIG. 7A, the outlines of the connections 1, 2 and 3 have been chosen partially differently in order to distinguish them better from the outlines of the measuring layer 10; in practice, however, at least at the common edges the lateral dimensions are ideally identical; this is also preferably the case in FIGS. 7A and 7B. Furthermore, as already explained with reference to FIG. 4, the resistance of the connections is ideally also substantially smaller than that of the measuring layer.

All the features explained up to this point or combinations of these features; also in connection with the patent claims, can be applied in the same way to the other embodiments of this application and combined with them. Some further embodiments are explained in more detail below.

FIGS. 8A and 8B show an exemplary embodiment (and FIG. 8C a slight variation thereof) in which two separate measuring layers 10, namely 11 and 12, are used for the two measurements with the aid of the measuring voltages U1, U2. Their layer thicknesses d correspond to each other, i.e. are in particular equal. In particular, it is a matter of partial layers or layer areas 10; 11, 12, which have been produced by one and the same pass through the printing or other deposition process and already therefore have the same layer thickness d. Preferably, these are partial layers or layer areas 10; 11, 12 which have not only been produced by the same type of printing or other deposition process, but have also been produced by the same execution or performance of this printing or other deposition process, i.e. by one and the same run of the process (the same experimental execution or performance of the process). The partial layers or layer areas 10; 11, 12 are thus jointly produced partial layers or layer areas, in particular simultaneously produced partial layers or layer areas. Depending on the type of deposition process, an initially uninterrupted layer can also be deposited and then the layer material on surrounding surface areas around the final layer areas 11, 12 can be removed again, for example etched back. But also in printing processes, the layer thickness d of the imprinted printing layer 5; 11, 12 is independent of the lateral position of the printed surface area; for example, of printing ink, printing varnish or printing paste 7.

The measurements with the measuring circuit 30 of FIGS. 8A, 8B are carried out analogously to FIGS. 2 to 7B, except that now two separate measuring layers 11, 12 and a total of four electrical connections 1, 2, 3, 4 are used, of which connections 3 and 4 are used for the resistance measurement at the first measuring layer 10; 11 in the direction of its layer thickness d and connections 3, 4 are used for the resistance measurement at the second measuring layer 10; 12 in the main extension direction or at least perpendicular to its layer thickness.

For the measurement in the direction of the layer thickness with the aid of the measuring voltage U1, a first measuring layer 11 with smaller lateral dimensions is required than for the measurement taking place transversely to the layer thickness and thus in the lateral direction with the second measuring layer 12. Nevertheless, as illustrated in FIG. 8C, both measuring layers 11, 12 can be designed with any desired dimensions, in particular also with the same area; the size of the contact surfaces of the connections can be adjusted accordingly. In the first measuring layer 11 for “vertical” resistance measurement of R1 (with current flow in the direction of the layer thickness d), for example, the surface dimensions of the connections 3, 4 are selected to be the same size as the outlines of the first measuring layer 11. In the second measuring layer 12 (for resistance measurement of R2 with current flow parallel to the main surfaces or undersides 10a, 10b), the contact surfaces of the connections 1, 2 are selected, for example, to be at most half as large as the area of the second measuring layer, in order to leave a distance between the two connections 1, 2 (distance 1 between the two connections in FIGS. 2 and 3).

FIG. 9 shows an exemplary embodiment in which several (first) measuring layers 10; 11, namely 11a and 11b for “vertical” resistance measurement (respective measuring voltage U1) and several (second) measuring layers 10; 12, namely 12a and 12b for “lateral” resistance measurement (measuring voltage U2) are provided. The measuring unit 30 or the device 50 equipped therewith may, for example, comprise a plurality of measuring layers 10 on the same substrate 25, carrier or other substrate, which may be arranged thereon in any number and/or in any arrangement relative to each other. It is also possible to have a plurality of measurement layers according to FIGS. 1 to 6, at each of which both vertical and lateral resistance can be measured, arranged together on a substrate. In FIGS. 8C and 9, the electrical leads of the respective electrical connections are no longer specifically illustrated. The lateral distances s (FIG. 8C) or s1 and s2 (FIG. 9) between adjacent measuring layers 10 can be smaller than, the same as or larger than the lateral dimensions of the respective measuring layers; it is only essential that the layer thickness d of all respective measuring layers or pressure layer surface areas is the same or (in the case of systematic deviation, for example as a result of decreasing or increasing layer thickness along a lateral direction) is in any case the same on a statistical average. Incidentally, if there are several pairs of resistors R1 and R2, the thickness d need only be constant locally in the extent of one pair.

If the thickness d is sufficiently accurate over a larger area, the number of vertical resistors can be reduced to a single one; then fewer resistors need to be printed and fewer calculus equations need to be considered). Namely, then the same mathematical calculation of the correct value of the desired parameter t, corrected for the influence of the layer thickness, can be performed similarly as explained with reference to FIGS. 1 to 6. Thus, if the layer thicknesses of the several measuring layers should deviate from each other, this layer thickness difference can be leveled by the resistance measurements on a plurality of respective first and second measuring layers 11, 12 (approximately as in FIG. 9), since the layer thickness deviations due to the areal distribution of the respective measuring layers over the substrate area 25 largely compensate for the respective calculation errors. Thus, the measurement result for the parameter t to be calculated is significantly more precise than with conventional measurements even if, for example, in FIG. 9 (or in an embodiment modified in some other way with a plurality of respective first/second measurement layers or with several measurement layers used in combination for both measurement directions), there is only a mean, average layer thickness, i.e. an average value d (averaged for all measurement layers involved). At least in printing processes, it is possible to generate layers with a constant area, i.e. with a uniform and thus spatially homogeneous layer thickness over the area to be printed; only the absolute value of these (always spatially homogeneous) layer thicknesses cannot be reliably predicted conventionally. But here, too, the measuring circuit 30 proposed here eliminates the additional effort conventionally required to determine the exact magnitude of the (possibly uniformly present but still unknown or yet to be measured) layer thickness of one or more measuring layers in order to calculate a correct value for the parameter t.

The measuring layers described in this application can, for example, be printing layers made of low-conductivity material, for example carbon, or low-conductivity foils; in the latter case, therefore, prefabricated material webs such as foils can also be applied as measuring layers, in particular glued on. It is thus not absolutely necessary that the measuring layer always be a printed or deposited layer. On the other hand, in the case of films or other material webs with their own dimensional stability, the layer thickness is often already known, so that there is no longer any need to measure the layer thickness. For example, platinum resistors can be used as measuring layers, in particular for the purpose of temperature measurement, with temperature as the parameter t; in this case, the formula for Rst(t) given further above represents the temperature dependence of the resistivity of the material of the measuring layer, in particular of platinum, whose characteristic curve is largely linear. Suitable materials for the electrical connections 1, 2, 3, 4 are, for example, silver pastes or silver conductive foils or other pastes or foils of conductive material; in particular of metals or metal alloys or other material mixtures. With regard to the measuring layers, the number of possible materials and material combinations is even more varied; it is essentially determined by the intended application of the device and the desired magnitude of the resistivity or electrical conductivity of this material. All specifications concerning the materials as well as with respect to the use of a plurality of measuring layers can be applied in an analogous manner to the exemplary embodiments still to be explained below.

FIGS. 10A and 10B show a further exemplary embodiment, from which it can be seen that the lateral dimensions of the measuring layer do not necessarily have to be rectangular. FIG. 10A shows a top view of the substrate 25 and FIG. 10B shows a cross-sectional view along a sectional plane along the direction y of FIG. 10A; a wire bridge 31 to the first connection 1, which is vertical in FIG. 10A, appears on the left side in FIG. 10B.

In this exemplary embodiment, which corresponds circuitry-wise to FIGS. 1 to 7B, three electrical connections 1, 2, 3 are likewise adjacent to a single measuring layer 10 of layer thickness d. However, here the measuring layer 10 is circular and allows a radial current flow or voltage drop of the second measuring voltage U2 (according to the lateral resistance R2) between the first connection 1, which is located on the underside 10a of the measuring layer 10 in the center below the measuring layer 10, and the second connection 2, which is also located on the underside but circularly below the outer edge region of the measuring layer 10. The lateral distance 1 from FIGS. 2 and 3 to be bridged perpendicular to the layer thickness d corresponds here to a radial distance between the outer radius of the underside first connection 1 and the inner radius of the underside second connection 2; the current path relevant for the second measurement voltage U2 runs in this annular area (but in the measurement layer 10 itself located above it, i.e. above the insulating filling layer 14, if present). Alternatively, the filling layer 14 can be omitted; the conformally deposited or printed measuring layer 10 then automatically fills the interstitial space at the same height as the two connections 1 and 2.

The measurement of the resistance in the direction of the layer thickness d is carried out with the aid of the first measuring voltage U1 (according to the “vertically” measured resistance R1) between the connections 2 and 3, which are both formed annularly (and with preferably the same surface dimensions; in particular the same inner and outer radius), but on opposite sides 10a; 10b of the measuring layer 10. The outer, annular measuring layer area between both connections 2, 3 is thus relevant for the measuring voltage U1 and an inner or at any rate middle measuring layer area between both connections 1, 2 is relevant for the measuring voltage U2.

For contacting the first connection 1 from the outside, a cutout is provided in the center of the measuring layer 10, which is filled with a contact hole filling 21; this is connected with a wire bridge 31, via which the voltage U2 between the first 1 and the second connection 2 can be tapped, because the first connection arranged centrally under the measuring layer is normally not accessible from the outside. The regions 1, 21 and 31 thus together form the first electrical connection 1, wherein the annular structure 1 below the contact hole filling 21 can be referred to as the first connection 1 in the narrower sense (or its contact or contact area region). Furthermore, the wire bridge 31 is insulated by an insulating layer 41 from the third connection 3 and also from the measuring layer itself; furthermore, the third connection 3 is insulated by an insulating layer 13 (FIG. 10A) at least from an outer region the second connection 2 at the outer periphery of the measuring layer 10.

A geometry of the measurement layer 10 according to FIGS. 10A and 10B may be chosen for a wide variety of reasons. This exemplary embodiment can be chosen, for example, in order to obtain a value for the parameter t to be calculated which corresponds to a mean value of the layer thickness d over the surface area of the measuring layer 10 which is as accurate as possible in the case of a not completely homogeneous course of the layer thickness d over the lateral dimensions of the measuring layer 10. Since not only the connections 2 and 3, but also the measuring layer 10 itself are mirror-symmetrical and inversion-symmetrical with respect to the symmetry axis or a mirror plane containing it (and thus also with respect to the first connection 1), a layer thickness profile for d, for example, in which d becomes increasingly larger in the direction x, is automatically leveled, since the first connection is located exactly in the center of the x dimension and since also the distance between the connections 2, 3 determined by the layer thickness d cannot assume a strongly deviating value, as would be conceivable with a geometry according to FIG. 7A or 8A. Of course, one or more measurement layers according to FIGS. 10A and/or 10B can also be provided in pairs or in even larger numbers together on a substrate 25 and/or combined with measurement layers of the other embodiments.

A further exemplary embodiment is illustrated in FIGS. 11A to 11C, namely in FIG. 11A as a cross-sectional view along a (rotational) axis of symmetry z and as two cross-sectional views perpendicular thereto, once at the level of the first connection 1 (FIG. 11C) and once at the level of the second and third connections 2, 3 (FIG. 11B).

The exemplary embodiment illustrates that a measuring layer 10 (and the plurality of connections 1, 2, 3 connected thereto) does not necessarily have to be planar, but can also be curved and, for example, cylindrical, such as hollow cylindrical. In particular, the measuring layer 10, as shown in FIG. 11A, is formed as a hollow cylinder with a larger length dimension in the direction of the axis of symmetry z; perpendicular to this, the layer thickness d extends along the radial direction r. The measuring layer 10 surrounds a cylindrical core which corresponds to the substrate 25 and can be formed here, for example, in the form of a rod, in particular as a (e.g. rod of a) probe 16 or measuring probe 17. The measuring layer 10 has been conformally deposited on the connections 1, 2 and the rod section between them, for example, after the connections 1, 2 have been applied to the outer radius of the rod 16, 17 around different length sections of the axial direction. The third connection 3 can then be deposited on an outer radius or an outer surface 10d of a measuring layer region surrounding the second connection 2. The inner surface 10c of the measuring layer has a smaller radius and contacts the outer radius of the second connection 2 and the first connection 1 spaced apart in the axial direction z. A planarizing insulating filling layer 14 may be provided between the connections 1, 2 below the measuring layer 10. The feed lines to the connections 1, 2, 3 are not specifically illustrated in FIGS. 11A to 11C.

FIGS. 11A to 11C thus exemplify a conceivable non-planar geometry of the measuring layer 10; here, too, both a resistance R1 in the direction of the layer thickness d of the (here hollow-cylindrical) measuring layer 10 (namely in the radial direction r; by means of the first voltage U1 between the connections 2, 3) and a resistance R2 in the direction perpendicular to the layer thickness d (namely in the axial direction z; by means of the second voltage U2 between the connections 1, 2) and by combining both measurements a value corrected for the influence of the layer thickness d can be calculated for the specific resistance or for the parameter t influencing this. The calculation formulas for this are, of course, different from those explained with reference to FIGS. 2 to 6 for the case of a rectangular measuring layer.

The device 50 proposed in this application and its measuring circuit 30 make it possible to compensate for the influence of the measurement layer thickness d on the measurement result. The device of this application can be used in all fields of application in which the determination of the layer thickness of the measuring layer and/or a correction or readjustment of the layer thickness is accompanied by technical difficulties or is associated with disproportionate additional effort.

FIG. 12 shows an embodiment, alternative to FIG. 1, of a device with at least one measuring layer. In contrast to the previous figures, in particular to FIG. 1, the measuring layer 10 is not necessarily a component of the measuring circuit 30; rather, the measuring circuit 30 can be an independent but integrated component of the device, in particular an evaluation electronics comprising the reference resistors shown in FIG. 5. The electrical connections 1, 2, 3, . . . may, for example, comprise conductor paths 51, 52, 53, . . . or connection leads (or vice versa); in particular, the connections 1, 2, 3, . . . directly adjacent to the measuring layer may be connected to the measuring circuit 30 by means of the conductor paths 51, 52, 53, . . . .

The device 50 of FIG. 1 or 12 may be formed according to any one of claims 1 to 13; in particular also with respect to its measuring circuit 30.

FIG. 13 shows an embodiment alternative to FIGS. 1 and 12, in which the device 50 comprises the measuring layer 10 (or a number of measuring layers 10 symbolized by dashed outlines) and the electrical connections 1, 2, 3, . . . (preferably including electrical conductor paths 51, 52, 53, . . . and/or preferably including external connections 1′, 2′, 3′, . . . ), but does not comprise its own measuring circuit. Instead, an independent measuring device 60 is provided which comprises the measuring circuit 30.

Although conceptually distinct from one another, the terms “measuring device 60” and “measuring circuit 30” in the embodiments of this application may alternatively be regarded as synonyms for one and the same unit; especially since the measuring device 60 is ultimately nothing other than the measuring circuit 30; plus a housing, if applicable.

Such a housing of the measuring device 60 and/or of the measuring circuit 30 may comprise own external connections 1″, 2″, 3″, . . . ) which are connectable with the external connections 1′, 2′, 3′, . . . ) of the device 50. In the measuring device 60 and/or in its measuring circuit 30, these external connections 1″, 2″, 3″, . . . ) may be connected by respective conductor paths 61, 62, 63, . . . or connection leads to corresponding connection points, contact points or nodes etc. of the measuring circuit 30 (or a sub-unit 30a thereof, for example of a chip or a printed circuit board etc.).

Thus, as an alternative to the previous FIGS. 1 to 12, FIG. 13 provides a device 50 which does not require its own measuring circuit, but which nevertheless enables electrical resistance measurements to be made at its measuring layer 10 (both parallel to and transverse to its layer thickness).

Further, FIG. 13 provides a measuring device 60 comprising the measuring circuit 30 for causing, performing and/or evaluating electrical resistance measurements on at least one measuring layer 10 (of any device 50 comprising such measuring layer 10). Also by means of this measuring device 60 or stand-alone, external measuring circuit 30, electrical resistance measurements can be made on measuring layers both in the direction parallel to and transverse to their layer thickness and the measurement results can be linked together as described above.

Thirdly, FIG. 13 provides an arrangement 100 (for making electrical measurements on at least one measurement layer), wherein the arrangement comprises the device 50 and the measurement device 60 according to both partial figures of FIG. 13.

The measuring device 60 or its measuring circuit 30 need only be connected temporarily, in extreme cases only once, with the device 50 in order to initiate, perform and/or evaluate the measurements on its measuring layer(s) 10.

The device 50 of FIG. 13 may be formed according to any one of claims 1 to 8 (i.e., without the measurement circuit 30). Further, the measuring device 60, which is shown only schematically as a unit in the figures (without illustration of its structure or circuit diagram), may be formed according to any one of claims 14 to 16.

In the arrangement 100 formed therefrom, the device 50 according to any one of claims 1 to 8 may be combined with a measuring device 60 according to any one of claims 14 to 16; whether merely associated with each other (e.g., the device in use permanently or temporarily and the measuring device normally stored separately from it, for only occasional measurement separately) or alternatively connected to each other (whether permanently or even temporarily).

### LIST OF REFERENCE SIGNS

1; 1′; 1″ first electrical connection
2; 2′; 2″ second electrical connection
3; 3′; 3″ third electrical connection
4; 4′; 4″ fourth electrical connection
5 printed layer
6 coating
7 printing paste
10 measuring layer
10a underside
10b upper side
10c Inner side
10d outer side
11; 11a; 11b first measuring layer
12; 12a; 12b second measuring layer
13 insulating layer
14 insulating filling layer
16 probe
17 measuring probe
21 contact hole filling
25 substrate
30 measuring circuit
30a subunit
31 wire bridge
40 sensor
41 insulating layer
45 Adjustment device
46 Heater
50 Device
51; 52; 53; 54 Connection lead
60 Measuring device
61; 62; 63; 64 connection lead
100 Arrangement
d; l1; d2 Layer thickness
d1; l2 Distance
b1; b2 Width
l; l′ length
r radial direction
R (ohmic) resistance
Rs specific resistance
Rst; Rst(t) resistivity (parameter dependent notation)
Rst_nom nominal value
R1; R2 resistance of the measuring layer
R1ref; R2ref reference resistance
s; s1; s2 distance
sf temperature coefficient
t parameter; temperature
Ub total voltage
U1 first voltage
U2 second voltage
x first lateral direction
y second lateral direction
z vertical direction

1: A device (50) for performing or at least enabling an electrical measurement on a measuring layer, wherein the device (50) comprises at least:
at least one measuring layer (10; 11, 12) having a layer thickness (d), and
a plurality of electrical connections (1, 2, 3, 4; 51, 52, 53, 54) connected to and/or adjacent to the at least one measurement layer (10; 11, 12) and serving to determine the electrical resistance of the at least one measurement layer (10; 11, 12), wherein at least some of the electrical connections (1, 2, 3, 4; 51, 52, 53, 54) are connected to or adjacent to different length portions of the at least one measuring layer (10; 11, 12), whereby a measurement for determining the electrical resistance of the at least one measuring layer (10; 11, 12) in the direction of its layer thickness (d) is carried out or at least made possible, and
wherein at least some of the electrical connections (1, 2, 3, 4; 51, 52, 53, 54) are connected to or adjacent to different, preferably mutually opposite surfaces of the at least one measuring layer (10; 11, 12), whereby a measurement for determining the electrical resistance of the at least one measuring layer (10; 11, 12) is carried out or at least made possible in the direction transverse to its layer thickness (d).

2: The device according to claim 1, wherein
the device (50) comprises a first electrical connection (1) and a second electrical connection (2), which are both adjacent to the at least one measuring layer (10; 11, 12) either on the underside (10a) or both on the upper side thereof and are spaced apart from one another in the direction (x) transverse to the layer thickness (d) of the at least one measuring layer (10; 11, 12), and
in the region between the two electrical connections (1, 2), the measuring layer (10; 11, 12) runs linearly, in the form of a web, in the form of a stretch or in some other way transversely with respect to its layer thickness (d).

3: The device according to claim 1, wherein
the device (50) comprises a third electrical connection (3) arranged on the opposite side of the measuring layer (10) opposite to the second electrical connection (2), namely on the upper side (10b) or underside of the measuring layer (10).

4: The device according to claim 1,
wherein
at least the second electrical connection (2) runs mirror-symmetrically on two mutually opposite sides of the first electrical connection (1), or
the first electrical connection (1) runs mirror-symmetrically on two mutually opposite sides of at least the second electrical connection (2).

5: The device according to claim 1,
wherein
at least the second electrical connection (2) surrounds the first electrical connection (1) in an annular or ring segment shape, or
the first electrical connection (1) surrounds at least the second electrical connection (2) in an annular or ring segment shape.

6: The device according to claim 1,
wherein
the at least one measuring layer (10; 11, 12) is cylindrical, in particular hollow cylindrical, wherein the first electrical connection (1) and the second electrical connection (2) are arranged on different axial length portions of the measuring layer (10), and wherein the second electrical connection (2) and the third electrical connection (3) are arranged in the same axial length portion of the measuring layer (10) on mutually opposite sides of the measuring layer (10), in particular on the inner side (10c) and the outer side (10d) of the measuring layer (10).

7: The device according to claim 1,
wherein
the device (50) comprises a plurality of separate measuring layers (10; 11, 12) whose layer thicknesses (d) correspond to one another, in particular are of the same size, wherein, with the aid of the electrical connections (1, 2, 3, 4; 51, 52, 53, 54), at a first measuring layer (10; 11) the ohmic resistance (R) can be measured and/or determined in the direction of the layer thickness (d) of the first measuring layer (10; 11) and at a second measuring layer (10; 12) the ohmic resistance (R) can be measured and/or determined in the direction transverse to the layer thickness (d) of the second measuring layer (10; 12) in order to calculate or have calculated from both measurements the value of the resistivity (Rst) of the measured layers (10; 11, 12) compensated for the influence of the layer thickness (d) and/or a parameter (t) influencing the resistivity (Rst).

8: The device according to claim 1,
wherein
the at least one measuring layer (10; 11, 12) is a coating (6) and/or a printed layer (5), for example a layer of printing paste or printing varnish.

9: The device according to claim 1,
wherein
the device (50) further comprises an electronic measuring circuit (30) that initiates, performs and/or evaluates both:
a measurement for determining the electrical resistance of the at least one measuring layer (10; 11, 12) in the direction of its layer thickness (d) and also
a measurement for determining the electrical resistance of the at least one measuring layer (10; 11, 12) in the direction transverse to its layer thickness (d);
wherein the device (50) and/or its measuring circuit (30) combines the results of both measurements and determines and/or calculates therefrom the following:
a) a value for the resistivity (Rst) of the at least one measurement layer (10; 11, 12), in which the influence of the layer thickness (d) and/or of variations in the layer thickness (d) is compensated for,
b) a value for a parameter (t) influencing the resistivity (Rst) of the at least one measuring layer (10; 11, 12), at which the influence of the layer thickness (d) and/or of variations of the layer thickness (d) is compensated, and/or
c) a value for the layer thickness (d) at which the influence of the resistivity (Rst) of the measuring layer (10; 11, 12) and/or of a parameter (t) influencing the resistivity (Rst) of the measuring layer (10; 11, 12) is compensated.

10: The device according to claim 9, wherein
the device (50) and/or its measuring circuit (30) combines the results of both measurements and determines and/or calculates therefrom:
a) a value for the resistivity (Rst) of the at least one measurement layer (10; 11, 12), in which the influence of the layer thickness (d) and/or of variations in the layer thickness (d) is compensated, and/or
b) a value for a parameter (t) influencing the resistivity (Rst) of the at least one measuring layer (10; 11, 12), at which the influence of the layer thickness (d) and/or of variations of the layer thickness (d) is compensated.

11: The device according to claim 1,
wherein the device (50) and/or its measurement circuit (30)
performs and/or enables the measurement of a first voltage (U1) which drops across the layer thickness (d) of the at least one measuring layer (10; 11, 12), by two electrical connections (2, 3), one electrical connection (2) of which is arranged on the underside (10a) of the at least one measuring layer (10; 11, 12) and the other electrical connection (3) of which is arranged on the upper side (10b) of the at least one measuring layer (10; 11, 12),
the measurement of a second voltage (U2), which drops over the distance of the at least one measuring layer (10; 11, 12) between the two electrical connections (1, 2) in the direction transverse to the layer thickness (d), is carried out and/or made possible by two electrical connections (1, 2) which adjoin the at least one measuring layer (10; 11, 12) at different surface regions of the latter which are spaced apart from one another along the course of the at least one measuring layer (10; 11, 12) transversely to its layer thickness (d), and
calculates or at least enables the calculation of a value of the resistivity (Rst) and/or of the parameter (t) influencing the resistivity (Rst), being independent of the layer thickness (d) of the at least one measuring layer (10; 11, 12) and compensated for the influence of the layer thickness (d), from both measurements.

12: The device according to claim 1,
wherein
the device (50) is a sensor (40) or comprises a sensor (40), wherein the sensor (40) enables measurement, calculation and/or determination of a value, compensated for the influence of the layer thickness (d) of the at least one measuring layer (10; 11, 12), for a parameter (t) influencing the resistivity (Rst) of the at least one measuring layer (10; 11, 12) and/or performs this itself with the aid of the measuring circuit (30).

13: The device according to claim 12, wherein
the sensor (40) or the other device (50) is configured such that
the dependence of the resistivity (Rst) on a parameter (t) and/or in dependence of the parameter (t) on the resistivity (Rst) of the at least one measuring layer (10; 11, 12) is approximated by a linear or other computational dependence around a nominal value, average value and/or estimated value of the layer thickness (d) of the at least one measuring layer (10; 11, 12), and
wherein the value of the resistivity (Rst) and/or of the parameter (t) compensated for the influence of the layer thickness (d) is calculated and/or determined using this linear or other computational dependence.

14: A measuring device (60) for carrying out an electrical measurement on at least one measuring layer, wherein the measuring device (60) comprises an electronic measuring circuit (30),
wherein the measuring device (60) and/or the measuring circuit (30) thereof initiates, carries out and/or evaluates both
a measurement for determining the electrical resistance of at least one measuring layer (10; 11, 12) in the direction of its layer thickness (d) and also
a measurement for determining the electrical resistance of at least one measuring layer (10; 11, 12) in the direction transverse to its layer thickness (d), and
wherein the measuring device (60) and/or its measuring circuit (30) combines the results of both measurements and determines and/or calculates therefrom the following:
a) a value for the resistivity (Rst) of the at least one measuring layer (10; 11, 12), wherein the influence of the layer thickness (d) and/or of fluctuations in the layer thickness (d) is compensated for in this value,
b) a value for a parameter (t) influencing the resistivity (Rst) of the at least one measuring layer (10; 11, 12), wherein the influence of the layer thickness (d) and/or of fluctuations of the layer thickness (d) is compensated for in this value, and/or
c) a value for the layer thickness (d) at which the influence of the resistivity (Rst) of the measuring layer (10; 11, 12) and/or of a parameter (t) influencing the resistivity (Rst) of the measuring layer (10; 11, 12) is compensated.

15: The measuring device (60) according to claim 14,
wherein
the measuring device (60) and/or its measuring circuit (30) combines the results of both measurements and determines and/or calculates therefrom:
a) a value for the resistivity (Rst) of at least one measuring layer (10; 11, 12), wherein in this value the influence of the layer thickness (d) and/or of fluctuations in the layer thickness (d) is compensated, and/or
b) a value for a parameter (t) influencing the resistivity (Rst) of at least one measuring layer (10; 11, 12), wherein the influence of the layer thickness (d) and/or of fluctuations in the layer thickness (d) is compensated for in this value.

16: The measuring device (60) according to claim 14,
wherein the measuring device (60) and/or its measuring circuit (30)
by two electrical connections (2″, 3″) initiates, carries out and/or evaluates the measurement of a first voltage (U1) which drops across the layer thickness (d) of at least one measuring layer (10; 11, 12),
by means of two electrical connections (1″, 2″), initiating, carrying out and/or evaluating the measurement of a second voltage (U2) on at least one measuring layer (10; 11, 12) in the direction transverse to the layer thickness (d), and
calculates from both measurements the value, compensated for the influence of the layer thickness (d) and independent of the layer thickness (d) of the at least one measuring layer (10; 11, 12), of the resistivity (Rst) and/or of the parameter (t) influencing the resistivity (Rst).

17: The measuring device (60) according to claim 14,
wherein
the measuring device and/or its measuring circuit (30) is configured in such a way that
the dependence of the resistivity (Rst) on a parameter (t) and/or the dependence of the parameter (t) on the resistivity (Rst) of the at least one measuring layer (10; 11, 12) is approximated by a linear or other computational dependence around a nominal value, average value and/or estimated value of the layer thickness (d) of the at least one measuring layer (10; 11, 12), and
wherein the value of the resistivity (Rst) and/or of the parameter (t) compensated for the influence of the layer thickness (d) is calculated and/or determined using this linear or other computational dependence.

18: An arrangement (100), comprising:
the device (50) according to claim 1; and
a measuring device (60) for carrying out an electrical measurement on at least one measuring layer, wherein the measuring device (60) comprises an electronic measuring circuit (30),
wherein the measuring device (60) and/or the measuring circuit (30) thereof initiates, carries out and/or evaluates both
a measurement for determining the electrical resistance of at least one measuring layer (10; 11, 12) in the direction of its layer thickness (d) and also
a measurement for determining the electrical resistance of at least one measuring layer (10; 11, 12) in the direction transverse to its layer thickness (d), and
wherein the measuring device (60) and/or its measuring circuit (30) combines the results of both measurements and determines and/or calculates therefrom the following:
a) a value for the resistivity (Rst) of the at least one measuring layer (10; 11, 12), wherein the influence of the layer thickness (d) and/or of fluctuations in the layer thickness (d) is compensated for in this value,
b) a value for a parameter (t) influencing the resistivity (Rst) of the at least one measuring layer (10; 11, 12), wherein the influence of the layer thickness (d) and/or of fluctuations of the layer thickness (d) is compensated for in this value, and/or
c) a value for the layer thickness (d) at which the influence of the resistivity (Rst) of the measuring layer (10; 11, 12) and/or of a parameter (t) influencing the resistivity (Rst) of the measuring layer (10; 11, 12) is compensated.

19: The device (50) according to claim 1,
wherein
with the aid of the device (50), as a parameter (t), a temperature of at least one measuring layer (10; 11, 12) and/or a temperature of a medium, material or volume surrounding at least one measuring layer (10; 11, 12) can be measured, calculated and/or determined.

20: The device (50) according to claim 1,
wherein
with the aid of the device (50), it is measurable, calculable and/or ascertainable as a parameter (t) a parameter which at least temporarily changes the nature of at least one measuring layer (10; 11, 12) or the surface thereof, for example a degree of moisture, a pressure, a brightness or radiation intensity, a pH value or a concentration or another quantity of a chemical, substance or component of a solution, an emulsion or suspension, a body fluid or any other medium.

21: The device (50) according to claim 1,
wherein the device (50) is an adjusting device (45) for adjusting a temperature (t) or another parameter (t) influencing the resistivity (Rs) of the at least one measuring layer (10; 11, 12), or comprises such an adjusting device (45), and
wherein the setting device (45) is such that, based on a monitored value for the temperature (t) or for the other parameter (t) compensated for the influence of the layer thickness (d) of at least one measuring layer (10; 11, 12), a desired level of the value of the temperature (t) or of the other parameter (t) is set, monitored and/or regulated.
